(19) United States
(12) Patent Application Publication
(10) Pub. No.: US 2025/0048851 A1
(43) Pub. Date: Feb. 6, 2025

(54) DISPLAY DEVICE

(71) Applicant: Samsung Display Co., Ltd., Yongin-Si (KR)

(72) Inventors: Kyung Bae KIM, Yongin-si (KR); Yong Hee LEE, Yongin-si (KR); Ji Hye LEE, Yongin-si, Gyeonggi-do (KR); Ki Hyun PYO, Yongin-si (KR)

(21) Appl. No.: 18/589,450

(22) Filed: Feb. 28, 2024

(30) Foreign Application Priority Data
Jul. 31, 2023 (KR) 10-2023-0100095

(51) Int. Cl. H10K 59/123; G02B 27/01; H10K 59/122; H10K 59/124

(52) U.S. Cl. CPC H10K 59/123; G02B 27/017; H10K 59/122; H10K 59/124; G02B 2027/0178

(57) ABSTRACT

The present disclosure relates to a display device, and more particularly, to a display device capable of improving the holding force of a spacer. The display device may include a substrate; a transistor on the substrate; a first electrode connected to the transistor, and a spacer disposed on the first electrode, wherein the spacer overlaps a connection portion between the transistor and the first electrode.

### CROSS-REFERENCE TO RELATED APPLICATION

This application claims priority from Korean Patent Application No. 10-2023-0100095 filed on Jul. 31, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, and more particularly, to a display device capable of improving the holding force of a spacer.

### 2. Description of the Related Art

A head mounted display (HMD) is an image display device that is worn on a user's head in the form of glasses or a helmet and focuses on a short distance in front of the user's eyes. The head mounted display may be used for virtual reality (VR) or augmented reality (AR) devices.

The head mounted display enlarges and displays an image displayed on a small display device using a plurality of lenses. Therefore, a display device applied to the head mounted display needs to provide a high-resolution image, for example, an image having a resolution of 3000 pixels per inch (PPI) or higher. To this end, organic light emitting diode on silicon (OLEDoS), which is a high-resolution, small organic light emitting display device, is used as the display device applied to the head mounted display. The OLEDOS is a device that displays an image by disposing an organic light emitting diode (OLED) on a semiconductor wafer substrate on which a complementary metal oxide semiconductor (CMOS) is disposed.

### SUMMARY

Aspects of the present disclosure provide a display device capable of improving the holding force of a spacer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Various benefits of the present disclosure will be apparent to those skilled in the art from the following descriptions.

According to an embodiment of the disclosure, a display device comprising: a substrate; a transistor on the substrate; a first electrode connected to the transistor; and a spacer disposed on the first electrode, wherein the spacer overlaps a connection portion between the transistor and the first electrode.

In an embodiment, there may be an insulating layer between the transistor and the first electrode, wherein the connection portion extends through a contact hole in the insulating layer.

In an embodiment, the spacer may overlap the contact hole.

In an embodiment, the first electrode may be disposed in the contact hole.

In an embodiment, the spacer may surround the first electrode in plan view and overlap the connection portion between the transistor and the first electrode.

In an embodiment, the spacer may include: a first sub-spacer disposed between the first electrodes of the adjacent rows; and a second sub-spacer disposed between the adjacent first sub-spacers and overlaps the connection portion between the transistor and the first electrode.

In an embodiment, the first sub-spacer may extend in the row direction, and wherein the second sub-spacer extends in the column direction intersecting the row direction.

In an embodiment, the second sub-spacer may be connected to the adjacent first sub-spacers.

In an embodiment, the second sub-spacer and the first sub-spacer may be integrally formed.

In an embodiment, the first sub-spacer may have a zig-zag form.

In an embodiment, the second sub-spacer may be disposed in plurality between the adjacent first sub-spacers.

In an embodiment, the first electrode may be disposed in a region surrounded and defined by the adjacent first sub-spacers and the adjacent second sub-spacers.

In an embodiment, there may be a pixel defining layer disposed between the first electrode and the spacer.

In an embodiment, the connection portion may extend through a contact hole in an insulating layer between the transistor and the first electrode, wherein a top surface of the pixel defining layer is at the same distance from the substrate in an overlapping area and a non-overlapping area with contact hole.

In an embodiment, pixel defining layer may have a trench surrounding the first electrode.

In an embodiment, the spacer may surround the trench.

In an embodiment, the spacer and the pixel defining layer may be integrally formed.

In an embodiment, there may be a partition wall disposed on the pixel defining layer.

In an embodiment, the partition wall may include: a lower layer on the pixel defining layer; and an upper layer on the lower layer.

In an embodiment, there may be a heating electrode on the spacer.

In an embodiment, the heating electrode may be disposed in a contact hole extending through the spacer and the pixel defining layer.

In an embodiment, the spacer may have a black color.

In an embodiment, there may be: an intermediate layer on the first electrode; and a second electrode on the intermediate layer.

According to the display device according to the present disclosure, the holding force of a spacer may be improved.

In addition, the difference in reflectance between areas where contact holes are placed and areas where contact holes are not placed is minimized, thereby improving image quality.

Also, since the spacer has a black color, external light reflection may be minimized, thereby improving image quality.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view illustrating a display device according to an embodiment;

FIG. 2 is a layout view illustrating an example of a display panel illustrated in FIG. 1;

FIG. 3 is a block diagram illustrating the display device according to an embodiment;

FIG. 4 is an equivalent circuit diagram of a first pixel according to an embodiment;

FIG. 5 is a layout view illustrating pixels of a display area according to an embodiment;

FIG. 6 is a cross-sectional view illustrating an example of the display device taken along line A-A′ of FIG. 5;

FIG. 7 is a perspective view illustrating a head mounted display device according to an embodiment;

FIG. 8 is an exploded perspective view illustrating an example of the head mounted display device of FIG. 7;

FIG. 9 is a perspective view illustrating a head mounted display device according to an embodiment;

FIG. 10 is a plan view of a display device according to an embodiment;

FIG. 11 is an enlarged view of portion A of FIG. 10;

FIG. 12 is a cross-sectional view of a display device taken along line I-I′ of FIG. 11;

FIG. 13 is a plan view of a display device according to an embodiment;

FIG. 14 is an enlarged view of portion B of FIG. 13;

FIG. 15 is a cross-sectional view of a display device taken along line II-II′ of FIG. 14;

FIG. 16 is a plan view of a display device according to an embodiment;

FIG. 17 is an enlarged view of portion C of FIG. 16;

FIG. 18 is a cross-sectional view of a display device taken along line III-III′ of FIG. 17; and

FIG. 19 is a plan view of a display device according to an embodiment.

### DETAILED DESCRIPTION OF THE EMBODIMENTS

Features of the present disclosure and methods to achieve them will become apparent from the descriptions of exemplary embodiments hereinbelow with reference to the accompanying drawings. However, the present disclosure is not limited to exemplary embodiments disclosed herein but may be implemented in various different ways. The exemplary embodiments are provided for making the disclosure of the present disclosure thorough and for fully conveying the scope of the present disclosure to those skilled in the art. The scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Ordinal terms such as first, second, etc. are used to distinguish arbitrarily between the elements, and do not necessarily indicate temporal or other prioritization of such elements. These terms are used to merely distinguish one element from another. Accordingly, as used herein, a first element and a second element may be interchanged within the technical scope of the present disclosure. As used herein, element A “overlapping” element B is intended to mean that one element partially or completely covers the other element, and the two elements may or may not be in direct contact.

Features of various exemplary embodiments of the present disclosure may be combined partially or totally. As will be clearly appreciated by those skilled in the art, technically various interactions and operations are possible. Various exemplary embodiments can be practiced individually or in combination.

Hereinafter, specific embodiments will be described with reference to the accompanying drawings.

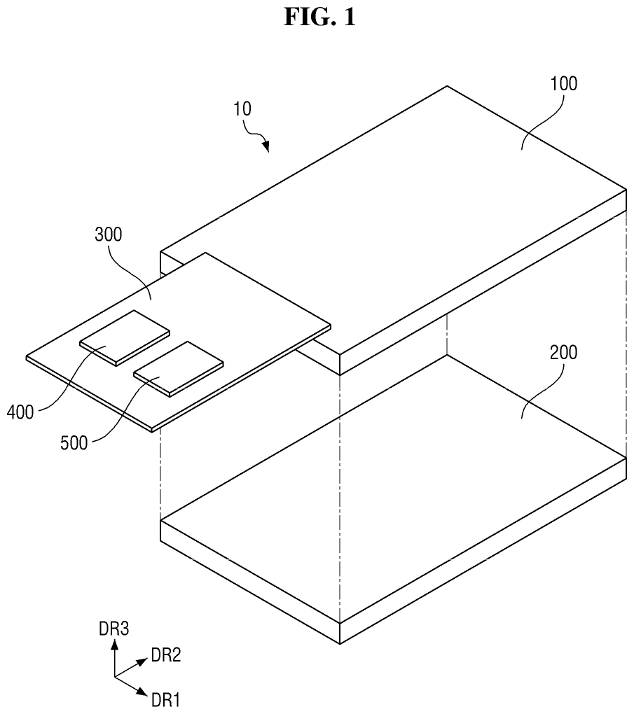

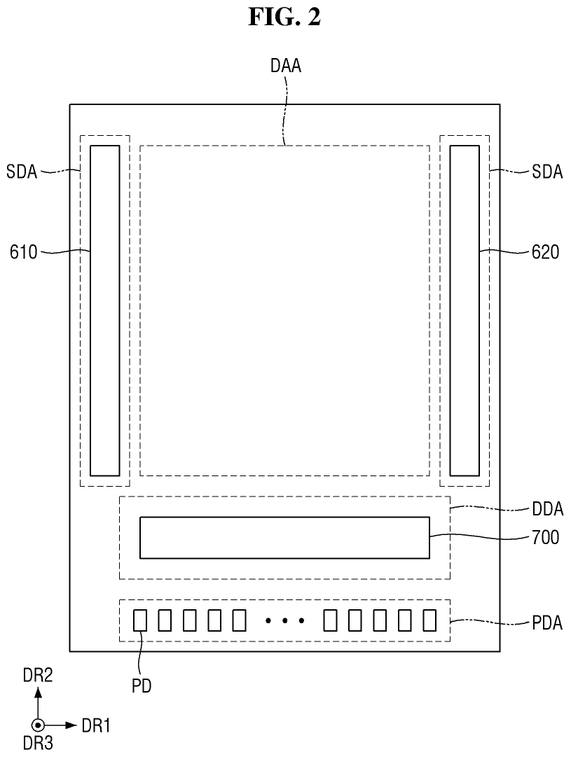

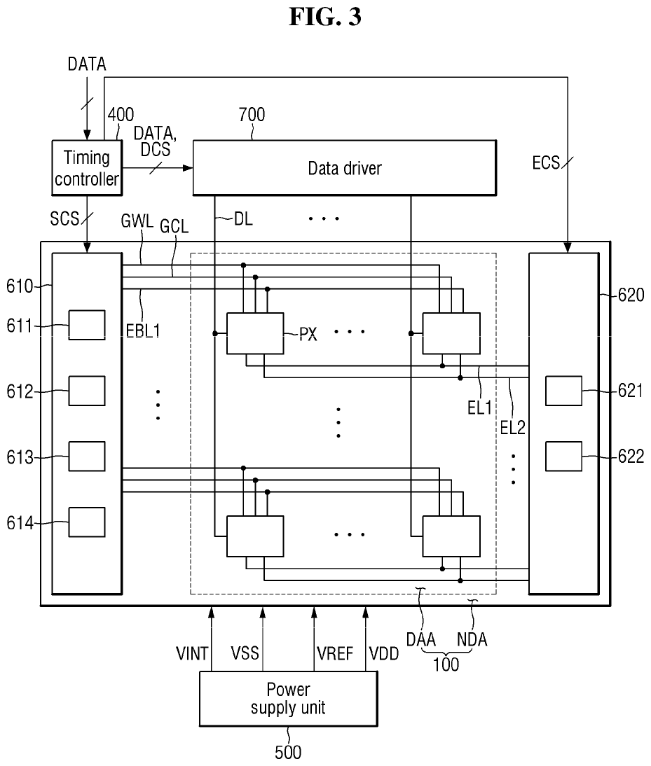

FIG. 1 is an exploded perspective view illustrating a display device according to an embodiment. FIG. 2 is a layout view illustrating an example of a display panel illustrated in FIG. 1. FIG. 3 is a block diagram illustrating the display device according to an embodiment.

Referring to FIGS. 1 and 2, a display device 10 according to an embodiment is a device displaying a moving image or a still image. The display device 10 according to an exemplary embodiment may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 may be applied to a display unit of a television, a laptop computer, a monitor, a billboard, or the Internet of Things (IoT). Alternatively, the display device 10 may be applied to a smart watch, a watch phone, and a head mounted display (HMD) for implementing virtual reality and augmented reality.

The display device 10 according to an embodiment includes a display panel 100, a heat dissipation layer 200, a circuit board 300, and a timing control circuit 400.

The display panel 100 may be formed in a planar shape similar to a quadrangle. For example, the display panel 100 may have a planar shape similar to a quadrangle having short sides in a first direction DR1 and long sides in a second direction DR2 intersecting the first direction DR1. In the display panel 100, a corner where the short side in the first direction DR1 and the long side in the second direction DR2 meet may be rounded to have a predetermined curvature or may be formed at a right angle. The planar shape of the display panel 100 is not limited to the quadrangle, and may be formed similarly to other polygons, circles, or ovals. A planar shape of the display device 10 may follow the planar shape of the display panel 100, but the embodiment of the present specification is not limited thereto.

As illustrated in FIG. 2, the display panel 100 includes a display area DAA displaying an image and a non-display area NDA that does not display an image.

The display area DAA includes a plurality of pixels PX, a plurality of scan lines SL, a plurality of emission control lines EL, and a plurality of data lines DL.

Each of the plurality of pixels PX includes a light emitting element emitting light. The plurality of pixels PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines EL1 and a plurality of second emission control lines EL2.

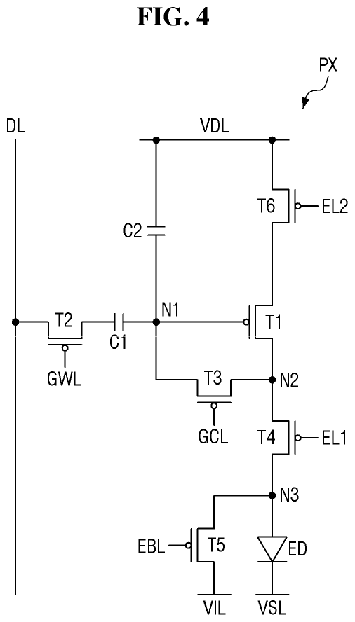

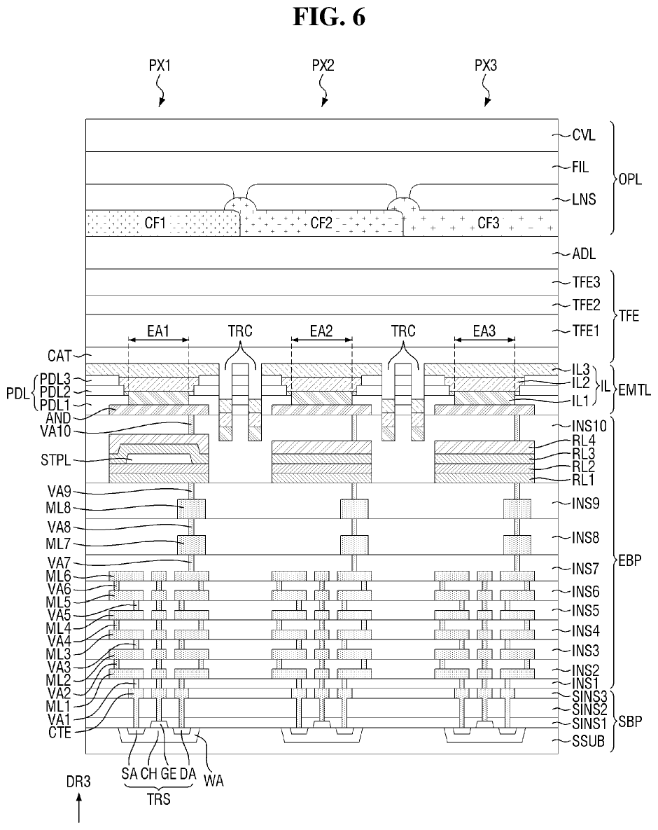

A plurality of unit pixels UPX include a plurality of pixels PX1, PX2, and PX3. The plurality of pixels PX1, PX2, and PX3 may include a plurality of pixel transistors as illustrated in FIG. 4, and the plurality of pixel transistors may be formed through a semiconductor process and may be disposed on a semiconductor substrate (SSUB in FIG. 6). For example, the plurality of pixel transistors may be formed of a complementary metal oxide semiconductor (CMOS).

Each of the plurality of pixels PX1, PX2, and PX3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of pixels PX1, PX2, and PX3 may receive a data voltage of the data line DL according to a write scan signal of the write scan line GWL, and may emit light from the light emitting element according to the data voltage.

The non-display area NDA includes a scan driving area SDA, a data driving area DDA, and a pad area PDA.

The scan driving area SDA may be an area in which a scan driver 610 and an emission driver 620 are disposed. It is illustrated in FIG. 2 that the scan driver 610 is disposed on the left side of the display area DAA, and the emission driver 620 is disposed on the right side of the display area DAA, but the embodiment of the present specification is not limited thereto. For example, the scan driver 610 and the emission driver 620 may be disposed on both the left and right sides of the display area DAA.

The scan driver 610 includes a plurality of scan transistors, and the emission driver 620 includes a plurality of light emitting transistors. The plurality of scan transistors and the plurality of light emitting transistors may be formed through a semiconductor process and may be formed on a semiconductor substrate (SSUB in FIG. 6). For example, the plurality of scan transistors and the plurality of light emitting transistors may be formed of CMOS.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from a timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driving area DDA may be an area in which a data driver 700 is disposed. The data driver 700 may include a plurality of data transistors, and the plurality of data transistors may be formed through a semiconductor process and may be formed on a semiconductor substrate (SSUB in FIG. 6). For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this case, the pixels PX1, PX2, and PX3 may be selected by the write scan signal of the scan driver 610, and the data voltages may be supplied to the selected pixels PX1, PX2, and PX3.

The pad area PDA includes a plurality of pads PD disposed in the first direction DR1. Each of the plurality of pads PD may be exposed without being covered by a cover layer (CVL in FIG. 6) and a polarizing plate (not illustrated).

The heat dissipation layer 200 may overlap the display panel 100 in a third direction DR3, which is a thickness direction of the display panel 100. The heat dissipation layer 200 may be disposed on one surface, for example, a rear surface of the display panel 100. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

The circuit board 300 may be electrically connected to the plurality of pads PD of the pad area PDA of the display panel 100 by using a conductive adhesive member such as an anisotropic conductive film. The circuit board 300 may be a flexible printed circuit board having a flexible material or a flexible film. Although FIG. 1 depicts the circuit board 300 in an unfolded state, the circuit board 300 may be bendable. In the bent state, one end of the circuit board 300 may be disposed on the rear surface of the display panel 100. One end of the circuit board 300 may be an opposite end of the other end of the circuit board 300 connected to the plurality of pads PD of the pad area PDA of the display panel 100 by using a conductive adhesive member.

The timing control circuit 400 may receive digital video data and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

The power supply circuit 500 may generate a plurality of panel driving voltages according to an external power voltage. For example, the power supply circuit 500 may generate and supply a first driving voltage VSS, a second driving voltage VDD, and a third driving voltage VINT to the display panel 100. A description of the first driving voltage VSS, the second driving voltage VDD, and the third driving voltage VINT will be described later with reference to FIG. 4.

Each of the timing control circuit 400 and the power supply circuit 500 may be formed as an integrated circuit (IC) and attached to one surface of the circuit board 300. The scan timing control signal SCS, the emission timing control signal ECS, the digital video data DATA, and the data timing control signal DCS of the timing control circuit 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

FIG. 4 is an equivalent circuit diagram of a first pixel according to an embodiment.

Referring to FIG. 4, the first pixel SPI may be connected to the write scan line GWL, the control scan line GCL, a bias scan line EBL, the first emission control line EL1, the second emission control line EL2, and the data line DL. In addition, the first pixel PX1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first pixel PX1 includes a plurality of transistors T1 to T6, a light emitting element ED, a first capacitor C1, and a second capacitor C2.

The light emitting element ED emits light according to a driving current Ids flowing through a channel of a first transistor T1. An amount of light emitted from the light emitting element ED may be proportional to the driving current Ids. The light emitting element ED may be disposed between a fourth transistor T4 and the first driving voltage line VSL. A first electrode of the light emitting element ED may be connected to a drain electrode of the fourth transistor T4, and a second electrode thereof may be connected to the first driving voltage line VSL. The first electrode of the light emitting element ED may be an anode electrode, and the second electrode of the light emitting element ED may be a cathode electrode. The light emitting element ED may be an organic light emitting diode including a first electrode, a second electrode, and an organic light emitting layer disposed between the first electrode and the second electrode, but the embodiment of the present specification is not limited thereto. For example, the light emitting element ED may be an inorganic light emitting device including a first electrode, a second electrode, and an inorganic semiconductor disposed between the first electrode and the second electrode. In this case, the light emitting element ED may be a micro light emitting diode.

The first transistor T1 may be a driving transistor that controls a source-drain current (Ids, hereinafter, referred to as “driving current”) flowing between a source electrode and a drain electrode according to a voltage applied to a gate electrode. The first transistor T1 includes a gate electrode connected to a first node N1, a source electrode connected to a drain electrode of a sixth transistor T6, and a drain electrode connected to a second node N2.

The second transistor T2 may be disposed between one electrode of the first capacitor C1 and the data line DL. The second transistor T2 is turned on by the write scan signal of the write scan line GWL and connects one electrode of the first capacitor C1 to the data line DL. Accordingly, the data voltage of the data line DL may be applied to one electrode of the first capacitor C1. The second transistor T2 includes a gate electrode connected to the write scan line GWL, a source electrode connected to the data line DL, and a drain electrode connected to one electrode of the first capacitor C1.

The third transistor T3 may be disposed between the first node N1 and the second node N2. The third transistor T3 is turned on by the write control signal of the write control line GCL and connects the first node N1 to the second node N2. Accordingly, since the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 and connects the second node N2 to the third node N3. Accordingly, the driving current of the first transistor T1 may be supplied to the light emitting element ED. The fourth transistor T4 includes a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 is turned on by the bias scan signal of the bias scan line EBL and connects the third node N3 to the third driving voltage line VIL. Accordingly, the third driving voltage VINT of the third driving voltage line VIL may be applied to the first electrode of the light emitting element ED. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a contact point of the gate electrode of the first transistor T1, the drain electrode of the third transistor T3, the other electrode of the first capacitor C1, and one electrode of the second capacitor C2. The second node N2 is a contact point of the drain electrode of the first transistor T1, the source electrode of the third transistor T3, and the source electrode of the fourth transistor T4. The third node N3 is a contact point of the drain electrode of the fourth transistor T4, the source electrode of the fifth transistor T5, and the first electrode of the light emitting element ED.

Each of the first to sixth transistors T1 to T6 may be a metal-oxide-semiconductor field effect transistor (MOSFET). For example, each of the first to sixth transistors T1 to T6 may be a P-type MOSFET, but the embodiment of the present specification is not limited thereto. Each of the first to sixth transistors T1 to T6 may be an N-type MOSFET. Alternatively, some of the first to sixth transistors T1 to T6 may be a P-type MOSFET, and the remaining transistors may be an N-type MOSFET.

It is illustrated in FIG. 4 that the first pixel PX1 includes six transistors T1 to T6 and two capacitors C1 and C2, but it should be noted that the equivalent circuit diagram of the first pixel PX1 is not limited to that illustrated in FIG. 4. For example, the number of transistors and capacitors of the first pixel PX1 is not limited to that illustrated in FIG. 4.

In addition, an equivalent circuit diagram of the second pixel PX2 and an equivalent circuit diagram of the third pixel PX3 may be substantially the same as the equivalent circuit diagram of the first pixel PX1 described with reference to FIG. 4. Therefore, descriptions of the equivalent circuit diagram of the second pixel PX2 and the equivalent circuit diagram of the third pixel PX3 are omitted in the present specification.

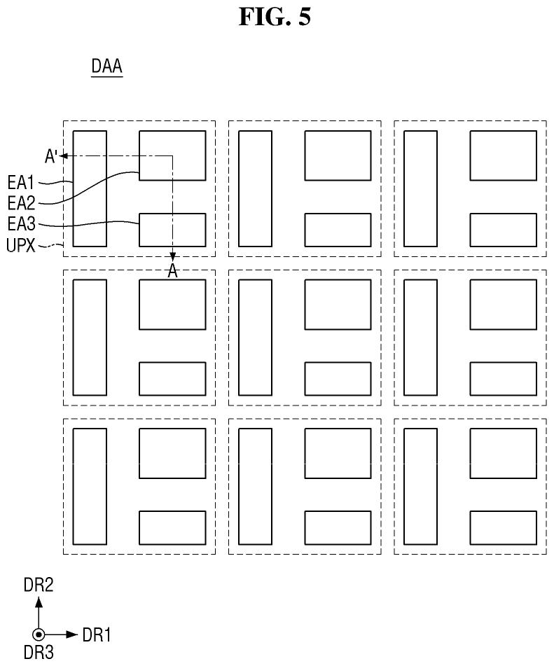

FIG. 5 is a layout view illustrating pixels of a display area according to an embodiment.

Referring to FIG. 5, each of the plurality of pixels PX includes a first light emitting area EA1, which is a light emitting area of the first pixel PX1, a second light emitting area EA2, which is a light emitting area of the second pixel PX2, and a third light emitting area EA3, which is a light emitting area of the third pixel PX3.

Each of the first light emitting area EA1, the second light emitting area EA2, and the third light emitting area EA3 may have a quadrangular planar shape such as a rectangle, a square, or a rhombus. For example, the first light emitting area EA1 may have a rectangular planar shape having a short side in the first direction DR1 and a long side in the second direction DR2. In addition, each of the second light emitting area EA2 and the third light emitting area EA3 may have a rectangular planar shape having a long side in the first direction DR1 and a short side in the second direction DR2.

A length of the first light emitting area EA1 in the first direction DR1 may be smaller than a length of the second light emitting area EA2 and a length of the third light emitting area EA3 in the first direction DR1. The length of the second light emitting area EA2 in the first direction DR1 and the length of the third light emitting area EA3 in the first direction DR1 may be substantially the same.

A length of the first light emitting area EA1 in the second direction DR2 may be greater than a sum of a length of the second light emitting area EA2 and a length of the third light emitting area EA3 in the second direction DR2. The length of the second light emitting area EA2 in the second direction DR2 may be greater than the length of the third light emitting area EA3 in the second direction DR2.

In the embodiment of FIG. 5, each of the first light emitting area EA1, the second light emitting area EA2, and the third light emitting area EA3 has a quadrangular planar shape. However, this is an exemplary embodiment of the present specification and not a limitation of the inventive concept. For example, each of the first light emitting area EA1, the second light emitting area EA2, and the third light emitting area EA3 may have a polygonal, circular, or elliptical planar shape other than the quadrangular shape.

In each of the plurality of pixels PX, the first light emitting area EA1 and the second light emitting area EA2 may be adjacent to each other in the first direction DR1. In addition, the first light emitting area EA1 and the third light emitting area EA3 may be adjacent to each other in the first direction DR1. In addition, the second light emitting area EA2 and the third light emitting area EA3 may be adjacent to each other in the second direction DR2. An area of the first light emitting area EA1, an area of the second light emitting area EA2, and an area of the third light emitting area EA3 may be different.

The first light emitting area EA1 emits light of a first color, the second light emitting area EA2 emits light of a second color, and the third light emitting area EA3 emits light of a third color. Here, the light of the first color may be light in a blue wavelength band, the light of the second color may be light in a green wavelength band, and the light of the third color may be light in a red wavelength band. For example, the blue wavelength band may indicate that a main peak wavelength of light is included in a wavelength band of approximately 370 nm to 460 nm, the green wavelength band may indicate that a main peak wavelength of light is included in a wavelength band of approximately 480 nm to 560 nm, and the red wavelength band may indicate that a main peak wavelength of light is included in a wavelength band of approximately 600 nm to 750 nm.

The embodiment of FIG. 5 depicts each of the plurality of pixels PX including three light emitting areas EA1, EA2, and EA3, but the present specification is not limited thereto. For example, each of the plurality of pixels PX may also include four light emitting areas.

In addition, the arrangement of the light emitting areas of the plurality of pixels PX is not limited to that illustrated in FIG. 5. For example, the light emitting areas of the plurality of pixels PX may be disposed in a stripe structure in which the light emitting areas are arranged in the first direction DR1, a PenTile® structure in which the light emitting areas have a diamond arrangement, or a hexagonal structure in which light emitting areas having a hexagonal planar shape are arranged.

FIG. 6 is a cross-sectional view illustrating an example of the display device taken along line A-A′ of FIG. 5.

Referring to FIG. 6, the display panel 100 includes a semiconductor backplane SBP, a light emitting element backplane EBP, a light emitting element layer EMTL, an encapsulation layer TFE, an optical layer OPL, a cover layer CVL, and a polarizing plate.

The semiconductor backplane SBP includes a semiconductor substrate SSUB including a plurality of pixel transistors TRS, a plurality of semiconductor insulating layers covering the plurality of pixel transistors TRS, and a plurality of contact terminals CTE electrically connected to the plurality of pixel transistors TRS, respectively. The plurality of pixel transistors TRS may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with first-type impurities. A plurality of well areas WA may be disposed on an upper surface of the semiconductor substrate SSUB. The plurality of well areas WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

Each of the plurality of well areas WA includes a source area SA corresponding to a source electrode of the pixel transistor TRS, a drain area DA corresponding to a drain electrode thereof, and a channel area CH disposed between the source area SA and the drain area DA.

Each of the source area SA and the drain area DA may be an area doped with first-type impurities. A gate electrode GE of the pixel transistor TRS may overlap the well area WA in the third direction DR3. The channel area CH may overlap the gate electrode GE in the third direction DR3. The source area SA may be disposed on one side of the gate electrode GE, and the drain area DA may be disposed on the other side of the gate electrode GE.

Each of the plurality of well areas WA further includes a first low-concentration impurity area LDD1 disposed between the channel area CH and the source area SA and a second low-concentration impurity area LDD2 disposed between the channel area CH and the drain area DA. The first low-concentration impurity area LDD1 may be an area having an impurity concentration lower than that of the source area SA. The second low-concentration impurity area LDD2 may be an area having an impurity concentration lower than that of the drain area DA. A distance between the source area SA and the drain area DA may be increased by the first low-concentration impurity area LDD1 and the second low-concentration impurity area LDD2. Therefore, since a length of the channel area CH of each of the pixel transistors TRS may increase, punch-through and hot carrier phenomena caused by a short channel may be prevented.

A first semiconductor insulating layer SINS1 may be disposed on the semiconductor substrate SSUB. The first semiconductor insulating layer SINS1 may be formed as a silicon carbon nitride (SiCN) or silicon oxide (SiOx)-based inorganic film, but the embodiment of the present specification is not limited thereto.

A semiconductor insulating layer SINS2 may be disposed on the first semiconductor insulating layer SINS1. The second semiconductor insulating layer SINS2 may be formed as a silicon oxide (SiOx)-based inorganic film, but the embodiment of the present specification is not limited thereto.

A plurality of contact terminals CTE may be disposed on the second semiconductor insulating layer SINS2. Each of the plurality of contact terminals CTE may be connected to any one of the gate electrode GE, the source area SA, and the drain area DA of each of the plurality of pixel transistors TRS through a hole penetrating through the first semiconductor insulating layer SINS1 and the second semiconductor insulating layer SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

A third semiconductor insulating layer SINS3 may be disposed on a side surface of each of the plurality of contact terminals CTE. An upper surface of each of the plurality of contact terminals CTE may be exposed without being covered by the third semiconductor insulating layer SINS3. The third semiconductor insulating layer SINS3 may be formed as a silicon oxide (SiOx)-based inorganic film, but the embodiment of the present specification is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that is not bent, and the polymer resin substrate may be a flexible substrate that may be bent or curved.

The light emitting element backplane EBP includes first to eighth metal layers ML1 to ML8, reflective metal layers RL1 to RL4, a plurality of vias VA1 to VA10, and a stepped layer STPL. In addition, the light emitting element backplane EBP includes a plurality of interlayer insulating layers INS1 to INS10 disposed between the first to sixth metal layers ML1 to ML6.

The first to eighth metal layers ML1 to ML8 serve to implement the circuit of the first pixel PX1 illustrated in FIG. 4 by connecting the plurality of contact terminals CTE exposed from the semiconductor backplane SBP. That is, only the first to sixth transistors T1 to T6 are formed on the semiconductor backplane SBP, and the first to sixth transistors T1 to T6 and the first and second capacitors C1 and C2 are connected through the first to eighth metal layers ML1 to ML8. In addition, the drain area corresponding to the drain electrode of the fourth transistor T4, the source area corresponding to the source electrode of the fifth transistor T5, and the first electrode of the light emitting element ED are also connected through the first to eighth metal layers ML1 to ML8.

A first interlayer insulating layer INS1 may be disposed on the semiconductor backplane SBP. Each of the first vias VA1 may penetrate through the first interlayer insulating layer INS1 and be connected to the contact terminal CTE exposed from the semiconductor backplane SBP. Each of the first metal layers ML1 may be disposed on the first interlayer insulating layer INS1 and may be connected to the first via VA1.

A second interlayer insulating layer INS2 may be disposed on the first interlayer insulating layer INS1 and the first metal layers ML1. Each of the second vias VA2 may be connected to the first metal layer ML1 exposed by penetrating through the second interlayer insulating layer INS2. Each of the second metal layers ML2 may be disposed on the second interlayer insulating layer INS2 and may be connected to the second via VA2.

A third interlayer insulating layer INS3 may be disposed on the second interlayer insulating layer INS2 and the second metal layers ML2. Each of the third vias VA3 may be connected to the second metal layer ML2 exposed by penetrating through the third interlayer insulating layer INS3. Each of the third metal layers ML3 may be disposed on the third interlayer insulating layer INS3 and may be connected to the third via VA3.

A fourth interlayer insulating layer INS4 may be disposed on the third interlayer insulating layer INS3 and the third metal layers ML3. Each of the fourth vias VA4 may be connected to the third metal layer ML3 exposed by penetrating through the fourth interlayer insulating layer INS4. Each of the fourth metal layers ML4 may be disposed on the fourth interlayer insulating layer INS4 and may be connected to the fourth via VA4.

A fifth interlayer insulating layer INS5 may be disposed on the fourth interlayer insulating layer INS4 and the fourth metal layers ML4. Each of the fifth vias VA5 may be connected to the fourth metal layer ML4 exposed by penetrating through the fifth interlayer insulating layer INS5. Each of the fifth metal layers ML5 may be disposed on the fifth interlayer insulating layer INS5 and may be connected to the fifth via VA5.

A sixth interlayer insulating layer INS6 may be disposed on the fifth interlayer insulating layer INS5 and the fifth metal layers ML5. Each of the sixth vias VA6 may be connected to the fifth metal layer ML5 exposed by penetrating through the sixth interlayer insulating layer INS6. Each of the sixth metal layers ML6 may be disposed on the sixth interlayer insulating layer INS6 and may be connected to the sixth via VA6.

A seventh interlayer insulating layer INS7 may be disposed on the sixth interlayer insulating layer INS6 and the sixth metal layers ML6. Each of the seventh vias VA7 may be connected to the sixth metal layer ML6 exposed by penetrating through the seventh interlayer insulating layer INS7. Each of the seventh metal layers ML7 may be disposed on the seventh interlayer insulating layer INS7 and may be connected to the seventh via VA7.

An eighth interlayer insulating layer INS8 may be disposed on the seventh interlayer insulating layer INS7 and the seventh metal layers ML7. Each of the eighth vias VA8 may be connected to the seventh metal layer ML7 exposed by penetrating through the eighth interlayer insulating layer INS8. Each of the eighth metal layers ML8 may be disposed on the eighth interlayer insulating layer INS8 and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. The first to eighth vias VA1 to VA8 may be formed of substantially the same material. The first to eighth interlayer insulating layers INS1 to INS8 may be formed as a silicon oxide (SiOx)-based inorganic film, but the embodiment of the present specification is not limited thereto.

A thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than a thickness (i.e., depth) of the first via VA1, a thickness of the second via VA2, a thickness of the third via VA3, a thickness of the fourth via VA4, a thickness of the fifth via VA5, and a thickness of the sixth via VA6, respectively. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same. For example, the thickness of the first metal layer ML1 may be approximately 1360 Å, each of the thickness of the second metal layer ML2, the thickness of the third metal layer ML3, the thickness of the fourth metal layer ML4, the thickness of the fifth metal layer ML5, and the thickness of the sixth metal layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be 1150 Å.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the thickness of the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same. For example, each of the thickness of the seventh metal layer ML7 and the thickness of the eighth metal layer ML8 may be approximately 9000 Å. Each of the thicknesses of the seventh via VA7 and the eighth via VA8 may be approximately 6000 Å.

A ninth interlayer insulating layer INS9 may be disposed on the eighth interlayer insulating layer INS8 and the eighth metal layers ML8. The ninth interlayer insulating layer INS9 may be formed as a silicon oxide (SiOx)-based inorganic film, but the embodiment of the present specification is not limited thereto.

Each of the ninth vias VA9 may be connected to the eighth metal layer ML8 exposed by penetrating through the ninth interlayer insulating layer INS9. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. A thickness of the ninth via VA9 may be approximately 16500 Å.

Each of first reflective electrodes RL1 may be disposed on the ninth interlayer insulating layer INS9 and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

Each of second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the second reflective electrodes RL2 may be formed of titanium nitride (TiN).

In the first pixel PX1, a stepped layer STPL may be disposed on the second reflective electrode RL2. The stepped layer STPL may not be disposed in each of the second pixel PX2 and the third pixel PX3. A thickness of the stepped layer STPL may be set in consideration of a wavelength of light of a first color and a distance from a first light emitting layer EML1 to a fourth reflective electrode RL4 to be advantageous in reflecting the light of the first color emitted from the first light emitting layer EML1 of the first pixel PX1. The stepped layer STPL may be formed of a silicon carbon nitride (SiCN) or silicon oxide (SiOx)-based inorganic film, but the embodiments of the present specification are not limited thereto. The thickness of the stepped layer STPL may be approximately 400 Å.

In the first pixel PX1, a third reflective electrode RL3 may be disposed on the second reflective electrode RL2 and the stepped layer STPL. In the second and third pixels PX2 and PX3, the third reflective electrode RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

At least one of the first reflective electrode RL1, the second reflective electrode RL2, and the third reflective electrode RL3 may be omitted.

Each of fourth reflective electrodes RL4 may be disposed on the third reflective electrode RL3. The fourth reflective electrodes RL4 may be layers that reflect light from first to third intermediate layers EML1, EML2, and EML3. The fourth reflective electrodes RL4 may include a metal having a high reflectance to be advantageous in reflecting light. The fourth reflective electrode RL4 may be formed of aluminum (Al), a stacked structure (Ti/Al/Ti) of aluminum and titanium, a stacked structure (ITO/Al/ITO) of aluminum and ITO, an APC alloy, which is an alloy of silver (Ag), palladium (Pd), and copper (Cu), and a stacked structure (ITO/APC/ITO) of an APC alloy and ITO, but the embodiment of the present specification is not limited thereto. A thickness of each of the fourth reflective electrodes RL4 may be approximately 850 Å.

A tenth interlayer insulating layer INS10 may be disposed on the ninth interlayer insulating layer INS9 and the fourth reflective electrode RL4. The tenth interlayer insulating layer INS10 may be formed as a silicon oxide (SiOx)-based inorganic film, but the embodiment of the present specification is not limited thereto.

Each of the tenth vias VA10 may be connected to a first electrode AND exposed by extending through the tenth interlayer insulating layer INS10. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. Due to the stepped layer STPL, a thickness of the tenth via VA10 in the first pixel PX1 may be smaller than a thickness of the tenth via VA10 in each of the second and third pixels PX2 and PX3. For example, the thickness of the tenth via VA10 in the first pixel PX1 may be approximately 800 Å, and the thickness of the tenth via VA10 in each of the second and third pixels PX2 and PX3 may be approximately 1200 Å.

The light emitting element layer EMTL may be disposed on the light emitting element backplane EBP. The light emitting element layer EMTL may include light emitting elements ED each including a first electrode AND, an intermediate layer IL, and a second electrode CAT, a pixel defining layer PDL, and a plurality of trenches TRC.

The first electrode AND of each of the light emitting elements ED may be disposed on the tenth interlayer insulating layer INS10 and may be connected to the tenth via VA10. The first electrode AND of each of the light emitting elements ED may be connected to the drain area DA or the source area SA of the pixel transistor TRS through the tenth via VA10, the first to fourth reflective electrodes RL1 to RL4, the first to ninth vias VA1 to VA9, the first to eighth metal layers ML1 to ML8, and the contact terminal CTE. The first electrode AND of each of the light emitting elements ED may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the first electrode AND of each of the light emitting elements ED may be formed of titanium nitride (TiN).

The pixel defining layer PDL may be disposed on a partial area of the first electrode AND of each of the light emitting elements ED. The pixel defining layer PDL may cover an edge of the first electrode AND of each of the light emitting elements ED. The pixel defining layer PDL serves to partition the first light emitting areas EA1, the second light emitting areas EA2, and the third light emitting areas EA3.

The first light emitting area EA1 may be defined as an area in which the first electrode AND, the intermediate layer IL, and the second electrode CAT are sequentially stacked in the first pixel PX1 to emit light. The second light emitting area EA2 may be defined as an area in which the first electrode AND, the intermediate layer IL, and the second electrode CAT are sequentially stacked in the second pixel PX2 to emit light. The third light emitting area EA3 may be defined as an area in which the first electrode AND, the intermediate layer IL, and the second electrode CAT are sequentially stacked in the third pixel PX3 to emit light.

The pixel defining layer PDL may include first to third pixel defining layers PDL1, PDL2, and PDL3. The first pixel defining layer PDL1 may be disposed on the edge of the first electrode AND of each of the light emitting elements ED, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed as a silicon oxide (SiOx)-based inorganic film, but the embodiment of the present specification is not limited thereto. Each of a thickness of the first pixel defining layer PDL1, a thickness of the second pixel defining layer PDL2, and a thickness of the third pixel defining layer PDL3 may be approximately 500 Å.

Each of the plurality of trenches TRC may penetrate through the first pixel defining layer PDL1, the second pixel defining layer PDL2, and the third pixel defining layer PDL3. Each of the plurality of trenches TRC may extend partially into the tenth interlayer insulating layer INS10.

At least one trench TRC may be disposed between the pixels PX1, PX2, and PX3 adjacent to each other. In the embodiment of FIG. 6, two trenches TRC are disposed between the pixels PX1 and PX2, and between pixels PX2 and PX3 that are adjacent to each other (and between pixels PX3 and the next PX1, although not explicitly shown). However, the present specification is not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2, and IL3 emitting different light. For example, the intermediate layer IL may include a first intermediate layer IL1 emitting light of a first color, a second intermediate layer IL2 emitting light of a third color, and a third intermediate layer IL3 emitting light of a second color. The first intermediate layer IL1, the second intermediate layer IL2, and the third intermediate layer IL3 may be sequentially stacked.

The first intermediate layer IL1 may have a structure in which a first hole transporting layer, a first organic light emitting layer emitting light of a first color, and a first electron transporting layer are sequentially stacked. The second intermediate layer IL2 may have a structure in which a second hole transporting layer, a second organic light emitting layer emitting light of a third color, and a second electron transporting layer are sequentially stacked. The third intermediate layer IL3 may have a structure in which a third hole transporting layer, a third organic light emitting layer emitting light of a second color, and a third electron transporting layer are sequentially stacked.

A first charge generation layer for supplying charges to the second intermediate layer IL2 and supplying electrons to the first intermediate layer IL1 may be disposed between the first intermediate layer IL1 and the second intermediate layer IL2. A second charge generation layer for supplying charges to the third intermediate layer IL3 and supplying electrons to the second intermediate layer IL2 may be disposed between the second intermediate layer IL2 and the third intermediate layer IL3.

The first intermediate layer IL1 may be disposed on the first electrodes AND and the pixel defining layer PDL, and may be disposed on a bottom surface of each of the trenches TRC. Due to the trench TRC, the first intermediate layer IL1 may be disconnected between the pixels PX1, PX2, and PX3 adjacent to each other. The second intermediate layer IL2 may be disposed on the first intermediate layer IL1. Due to the trench TRC, the second intermediate layer IL2 may be disconnected between the pixels PX1, PX2, and PX3 adjacent to each other. The third intermediate layer IL3 may be disposed on the second intermediate layer IL2. Due to the trench TRC, the third intermediate layer IL3 may be disconnected between the pixels PX1, PX2, and PX3 adjacent to each other. That is, each of the plurality of trenches TRC may be a structure for disconnecting the first to third intermediate layers IL1, IL2, and IL3 of the light emitting element layer EMTL between the pixels PX1, PX2, and PX3 adjacent to each other.

In order to stably disconnect the first to third intermediate layers IL1, IL2, and IL3 of the light emitting element layer EMTL between the pixels PX1, PX2, and PX3 adjacent to each other, a depth of each of the plurality of trenches TRC may be greater than the thickness of the pixel defining layer PDL. The depth of each of the plurality of trenches TRC indicates a length of each of the plurality of trenches TRC in the third direction DR3. The thickness of the pixel defining layer PDL indicates a length of the pixel defining layer PDL in the third direction DR3.

In order to disconnect the first to third intermediate layers IL1, IL2, and IL3 of the light emitting element layer EMTL between the pixels PX1, PX2, and PX3 adjacent to each other, other structures may be present instead of the trench TRC. For example, instead of the trench TRC, a partition wall having a reverse tapered shape may be disposed on the pixel defining layer PDL.

The number of intermediate layers IL1, IL2, and IL3 emitting different lights is not limited to what is illustrated in FIG. 6. For example, the intermediate layer IL may include two intermediate layers. In this case, one of the two intermediate layers may be substantially the same as the first intermediate layer IL1, and the other thereof may include a second hole transporting layer, a second organic light emitting layer, a third organic light emitting layer, and a second electron transporting layer. In this case, a charge generation layer for supplying electrons to one intermediate layer and supplying charges to the other intermediate layer may be disposed between the two intermediate layers.

In addition, it is illustrated in FIG. 6 that the first to third intermediate layers IL1, IL2, and IL3 are all disposed in the first light emitting area EA1, the second light emitting area EA2, and the third light emitting area EA3, but the embodiment of the present specification is not limited thereto. For example, the first intermediate layer IL1 may be disposed in the first light emitting area EA1 and may not be disposed in the second light emitting area EA2 and the third light emitting area EA3. In addition, the second intermediate layer IL2 may be disposed in the second light emitting area EA2 and may not be disposed in the first light emitting area EA1 and the third light emitting area EA3. In addition, the third intermediate layer IL3 may be disposed in the third light emitting area EA3 and may not be disposed in the first light emitting area EA1 and the second light emitting area EA2. In this case, first to third color filters CF1, CF2, and CF3 of the optical layer OPL may be omitted.

The second electrode CAT may be disposed on the third intermediate layer IL3. The second electrode CAT may be disposed on the third intermediate layer IL3 in each of the plurality of trenches TRC. The second electrode CAT may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). When the second electrode CAT is formed of a semi-transmissive conductive material, light emission efficiency may be increased in each of the first to third pixels PX1, PX2, and PX3 by micro cavities.

The encapsulation layer TFE may be disposed on the light emitting element layer EMTL. The encapsulation layer TFE may include one or more inorganic films TFE1 and TFE2 to prevent oxygen or moisture from permeating into the light emitting element layer EMTL. In addition, the encapsulation layer TFE may include at least one organic film to protect the light emitting element layer EMTL from foreign substances such as dust. For example, the encapsulation layer TFE may include a first encapsulation inorganic layer TFE1, an encapsulation organic layer TFE2, and a second encapsulation inorganic layer TFE3.

The first encapsulation inorganic layer TFE1 may be disposed on the second electrode CAT, the encapsulation organic layer TFE2 may be disposed on the first encapsulation inorganic layer TFE1, and the second encapsulation inorganic layer TFE3 may be disposed on the encapsulation organic layer TFE2. The first encapsulation inorganic layer TFE1 and the second encapsulation inorganic layer TFE3 may be formed as multiple layers in which one or more inorganic layers of a silicon nitride layer (SiNx), a silicon oxynitride layer (SiON), a silicon oxide layer (SiOx), a titanium oxide layer (TiOx), and an aluminum oxide layer (AlOx) are alternately stacked. The encapsulation organic layer TFE2 may be a monomer. In addition, the encapsulation organic layer TFE2 may be an organic layer made of an acrylic resin, an epoxy resin, a phenolic resin, a polyamide resin, or a polyimide resin.

An adhesive layer ADL may be a layer for attaching the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the adhesive layer ADL.

The first color filter CF1 may overlap the first light emitting area EA1 of the first pixel PX1. The first color filter CF1 may transmit light of a first color, that is, light in a blue wavelength band. The blue wavelength band may be approximately 370 nm to 460 nm. Therefore, the first color filter CF1 may transmit light of a first color among light emitted from the first light emitting area EA1.

The second color filter CF2 may overlap the second light emitting area EA2 of the second pixel PX2. The second color filter CF2 may transmit light of a second color, that is, light in a green wavelength band. The green wavelength band may be approximately 480 nm to 560 nm. Therefore, the second color filter CF2 may transmit light of a second color among light emitted from the second light emitting area EA2.

The third color filter CF3 may overlap the third light emitting area EA3 of the third pixel PX3. The third color filter CF3 may transmit light of a third color, that is, light in a red wavelength band. The red wavelength band may be approximately 600 nm to 750 nm. Therefore, the third color filter CF3 may transmit light of a third color among light emitted from the third light emitting area EA3.

Each of the plurality of lenses LNS may be disposed on each of the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index so that light travels in the third direction DR3 at an interface between the plurality of lenses LNS and the filling layer FIL. In addition, the filling layer FIL may be a planarization layer. The filling layer FIL may be an organic film made of an acryl resin, an epoxy resin, a phenolic resin, a polyamide resin, or a polyimide resin.

The cover layer CVL may be disposed on the filling layer FIL. The cover layer CVL may be a glass substrate or a polymer resin such as resin. When the cover layer CVL is a glass substrate, the cover layer CVL may be attached onto the filling layer FIL. In this case, the filling layer FIL may serve to adhere the cover layer CVL. When the cover layer CVL is a glass substrate, the cover layer CVL may serve as an encapsulation substrate. When the cover layer CVL is a polymer resin such as resin, the cover layer CVL may be directly applied on the filling layer FIL.

The polarizing plate may be disposed on one surface of the cover layer CVL. The polarizing plate may be a structure for preventing deterioration in visibility due to reflection of external light. The polarizing plate may include a linear polarizing plate and a phase retardation film. For example, the phase retardation film may be a λ/4 (quarter-wave) plate, but the embodiment of the present specification is not limited thereto. However, when deterioration in visibility due to reflection of external light is sufficiently improved by the first to third color filters CF1, CF2, and CF3, the polarizing plate may also be omitted.

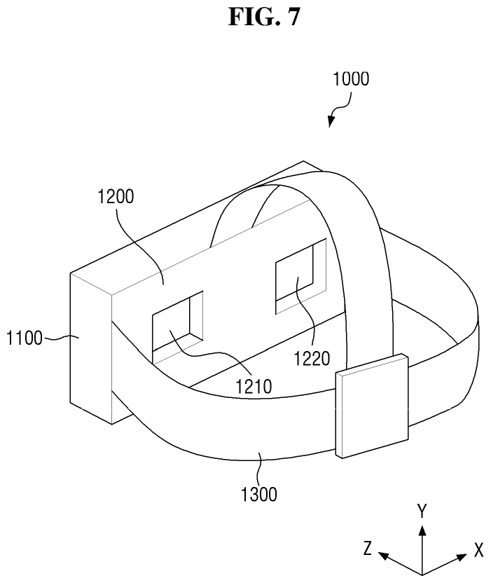

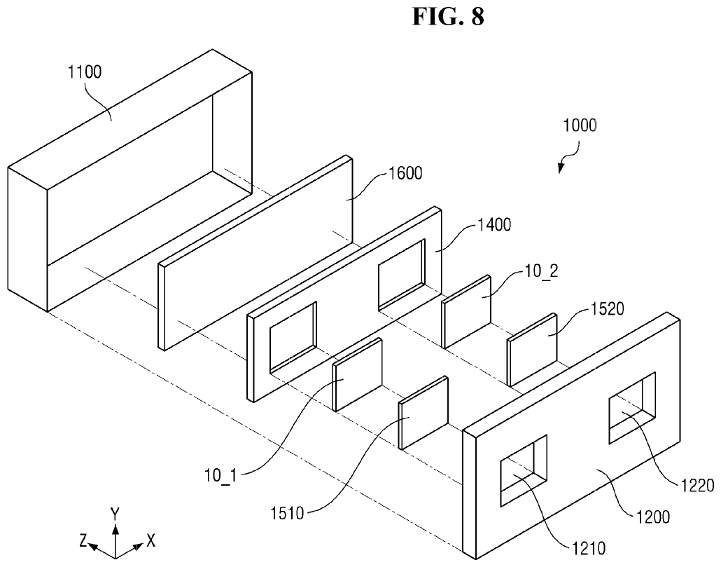

FIG. 7 is a perspective view illustrating a head mounted display device according to an embodiment. FIG. 8 is an exploded perspective view illustrating an example of the head mounted display device of FIG. 7.

Referring to FIGS. 7 and 8, a head mounted display device 1000 as an optical device according to an embodiment includes a first display device 10_1, a second display device 10_2, an image generator 1100, an image generator cover 1200, a first eyepiece lens 1210, a second eyepiece lens 1220, a head mounting band 1300, a middle frame 1400, a first optical member 1510, a second optical member 1520, a control circuit board 1600, and a connector.

The first display device 10_1 provides an image to the user's left eye, and the second display device 10_2 provides an image to the user's right eye. Since each of the first display device 10_1 and the second display device 10_2 is substantially the same as the display device 10 described with reference to FIGS. 1 to 6, descriptions of the first display device 10_1 and the second display device 10_2 are omitted.

The first optical member 1510 may be disposed between the first display device 10_1 and the first eyepiece lens 1210. The second optical member 1520 may be disposed between the second display device 10_2 and the second eyepiece lens 1220. Each of the first optical member 1510 and the second optical member 1520 may include at least one convex lens.

The middle frame 1400 may be disposed between the first display device 10_1 and the control circuit board 1600 and may be disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the image generator 1100. The control circuit board 1600 may be connected to the first display device 10_1 and the second display device 10_2 through a connector 1610. The control circuit board 1600 may convert an image source input from the outside into digital video data DATA, and may transmit the digital video data DATA to the first display device 10_1 and the second display device 10_2 through the connector 1610.

The control circuit board 1600 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The image generator 1100 serves to accommodate the first display device 10_1, the second display device 10_2, the middle frame 1400, the first optical member 1510, the second optical member 1520, the control circuit board 1600, and the connector 1610. The image generator cover 1200 is disposed to cover one opened surface of the image generator 1100. The image generator cover 1200 may include a first eyepiece lens 1210 that is for the user's left eye and a second eyepiece lens 1220 that is for the user's right eye. Although FIGS. 7 and 8 depict the first eyepiece lens 1210 and the second eyepiece lens 1220 being separately disposed, this is not a limitation of the present specification. For example, the first eyepiece lens 1210 and the second eyepiece lens 1220 may be integrated into one long eyepiece.

The first eyepiece lens 1210 may be aligned with the first display device 10_1 and the first optical member 1510, and the second eyepiece lens 1220 may be aligned with the second display device 10_2 and the second optical member 1520. Therefore, the user may view an image of the first display device 10_1 magnified as a virtual image by the first optical member 1510 through the first eyepiece lens 1210, and may view an image of the second display device 10_2 magnified as a virtual image by the second optical member 1520 through the second eyepiece lens 1220.

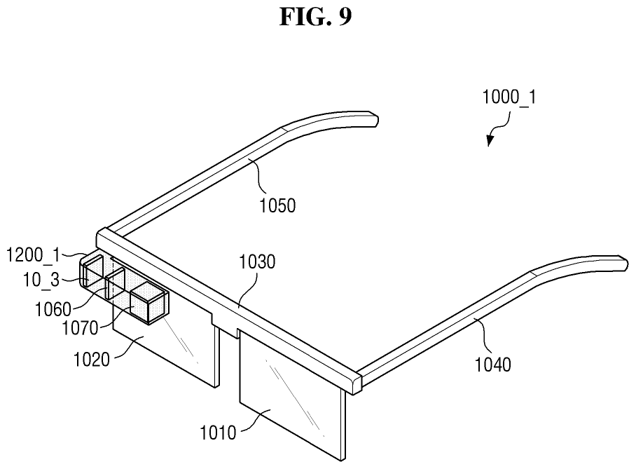

The head mounting band 1300 serves to fix the image generator 1100 to a user's head so that the first eyepiece lens 1210 and the second eyepiece lens 1220 of the image generator cover 1200 are disposed on the user's left and right eyes, respectively. When the image generator 1100 is implemented in a lightweight and small size, the head mounted display device 1000 may include eyeglass frames as illustrated in FIG. 9 instead of the head mounting band 1300.

In addition, the head mounted display device 1000 may further include a battery for supplying power, an external memory slot for accommodating an external memory, and an external connection port and a wireless communication module for receiving an image source. The external connection port may be a universal serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 9 is a perspective view illustrating a head mounted display device according to an embodiment.

Referring to FIG. 9, a head mounted display device 1000_1 according to an embodiment may be a glasses-type display device in which an image generator 1200_1 is implemented in a lightweight and small housing. The head mounted display device 1000_1 according to an embodiment may include a display device 10_3, a left eye lens 1010, a right eye lens 1020, a support frame 1030, eyeglass frame legs 1040 and 1050, an optical member 1060, an optical path conversion member 1070, and an image generator 1200_1.

The image generator 1200_1 may house the display device and optical components. More specifically, the display portion 1200_1 may include the display device 10_3, the optical member 1060, and the optical path conversion member 1070. As an image displayed on the display device 10_3 is magnified by the optical member 1060 and an optical path thereof is converted by the optical path conversion member 1070, the image may be provided to the user's right eye through the right eye lens 1020. Accordingly, the user may view an augmented reality image in which a virtual image displayed on the display device 10_3 and a real image seen through the right eye lens 1020 are combined through the right eye.

It is illustrated in FIG. 9 that the image generator 1200_1 is disposed at a right distal end of the support frame 1030, but the embodiment of the present specification is not limited thereto. For example, the image generator 1200_1 may be disposed at a left distal end of the support frame 1030, and in this case, the image of the display device 10_3 may be provided to the user's left eye. Alternatively, the image generator 1200_1 may be disposed at both the left and right distal ends of the support frame 1030. In this case, the user may view the image displayed on the display device 10_3 through both the user's left and right eyes.

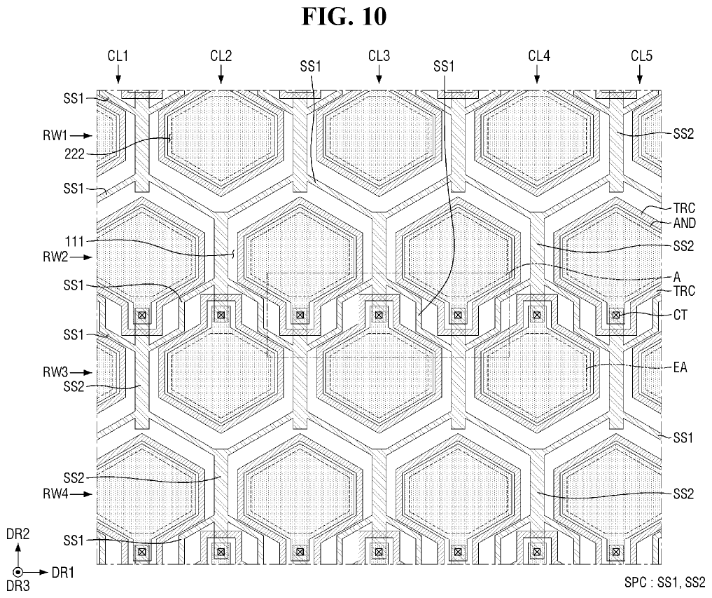

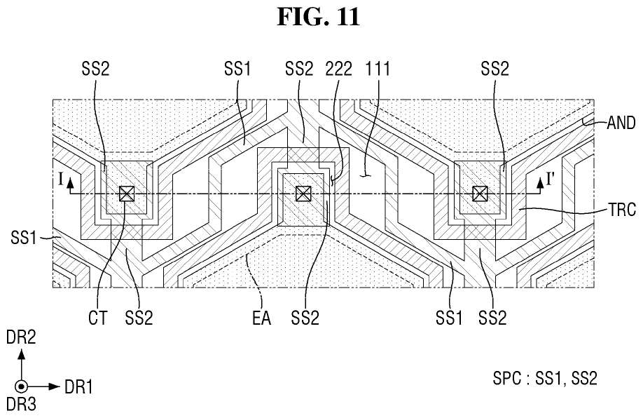

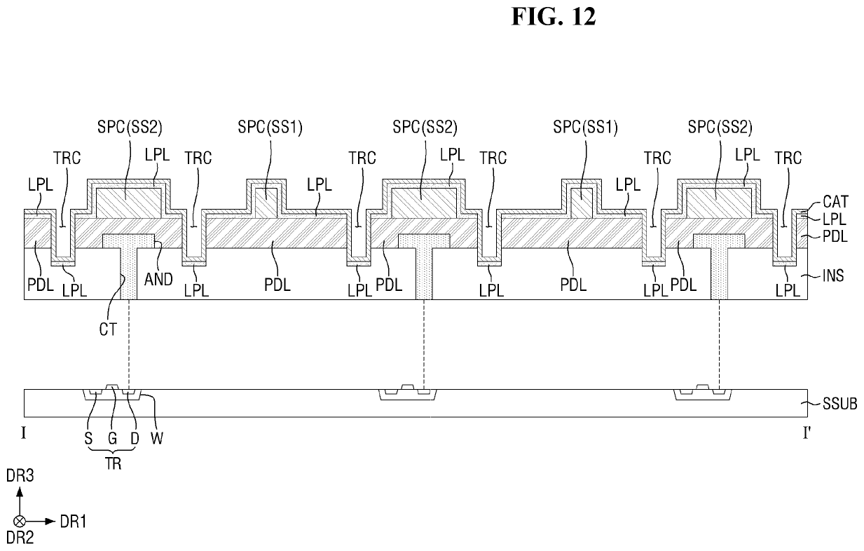

FIG. 10 is a plan view of a display device according to an embodiment, FIG. 11 is an enlarged view of portion A of FIG. 10, and FIG. 12 is a cross-sectional view of a display device taken along line I-I′ of FIG. 11.

As illustrated in FIGS. 10 to 12, the display device 10 may include a substrate SSUB, a transistor TR, an insulating layer INS, an anode electrode AND (e.g., a first electrode), a pixel defining layer PDL, a spacer SPC, an intermediate layer LPL, and a cathode electrode CAT (e.g., a second electrode).

As illustrated in FIG. 12, the transistor TR may be disposed on the substrate SSUB. The transistor TR may include a gate electrode G, a source electrode S, and a drain electrode D. The source electrode S and the drain electrode D may be disposed in the well region W of the substrate SSUB. The transistor TR illustrated in FIG. 12 may be, for example, the fourth transistor T4 of FIG. 4 described above.

As illustrated in FIG. 12, the anode electrode AND may be connected to the transistor TR through a contact hole CT extending through the insulating layer INS. For example, the anode electrode AND may be connected to the drain electrode D of the transistor TR through the contact hole CT of the insulating layer INS. A portion of the anode electrode AND may be disposed within the contact hole CT of the insulating layer INS. Here, the insulating layer INS may be an interlayer insulating layer INS disposed between the substrate SSUB and the anode electrode AND. For example, the insulating layer INS of FIG. 12 may be the tenth interlayer insulating layer INS10 of FIG. 6 described above. In addition, the contact hole CT of FIG. 12 may be the tenth via VA10 of FIG. 6.

As illustrated in FIGS. 10 and 11, a plurality of first (anode) electrodes AND may be provided. In other words, the display device 10 may include a plurality of anode electrodes AND. According to an embodiment, the plurality of anode electrodes AND may be arranged along a plurality of rows and a plurality of columns. A plurality of anode electrodes AND arranged along four rows RW1, RW2, RW3, and RW4 and five columns CL1, CL2, CL3, CL4, and CL5 are exemplified in FIG. 10.

As illustrated in FIG. 12, the pixel defining layer PDL may be disposed on the anode electrode AND. As illustrated in FIGS. 10 and 11, the pixel defining layer PDL may define a light emitting area EA of the pixel. To this end, the pixel defining layer PDL may be, for example, disposed to expose a portion of the anode electrode AND on the insulating layer INS. The pixel defining layer PDL may cover the edge of the anode electrode AND. The pixel defining layer PDL may be formed as an organic film made of an acryl resin, an epoxy resin, a phenolic resin, a polyamide resin, or a polyimide resin.

As illustrated in FIG. 12, a spacer SPC may be disposed on the pixel defining layer PDL.

As illustrated in FIGS. 10 and 11, from a plan view, the spacer SPC may surround the anode electrode AND and a trench TRC which will be described later. For example, as illustrated in FIG. 10, the spacer SPC may define a spacer area 111 surrounded by the spacer SPC, and from a plan view, the anode electrode AND and the trench TRC described above may be disposed within this spacer area 111. At this time, at least a portion of the spacer SPC may overlap a connection portion (e.g., a contact hole CT of the insulating layer INS) between the anode electrode AND and the transistor TR described above.

The spacer SPC may have a black color so that reflection of external light can be minimized. For example, the surface of the spacer SPC may be coated with black dye or the like.

As illustrated in FIGS. 10 and 11, the spacer SPC may include a first sub-spacer SS1 and a second sub-spacer SS2.

As illustrated in FIG. 10, the first sub-spacer SS1 may be disposed between the anode electrodes AND in adjacent rows. For example, the first sub-spacer SS1 may be disposed between the anode electrode AND of the first row RW1 and the anode electrode AND of the second row RW2. In addition, the first sub-spacer SS1 may be disposed between the anode electrode AND in the second row RW2 and the anode electrode AND in the third row RW3. In addition, the first sub-spacer SS1 may be disposed between the anode electrode AND of the third row RW3 and the anode electrode AND of the fourth row RW4.

The first sub-spacer SS1 may extend generally along the row direction (e.g., first direction DR1).

The first sub-spacer SS1 may have a zig-zag shape that generally extends in the first direction DR1.

The second sub-spacer SS2 may be disposed between adjacent first sub-spacers SS1. For example, referring to the first sub-spacer SS1 disposed between the anode electrode AND of the first row RW1 and the anode electrode AND of the second row RW2 as a first-first sub-spacer, and referring to the first sub-spacer SS1 disposed between the anode electrode AND of the second row RW2 and the anode electrode AND of the third row RW3 as a first-second sub spacer, the second sub-spacer SS2 may be disposed between the first-first sub-spacer and the first-second sub spacer.

The second sub-spacer SS2 may extend in a different direction from the first sub-spacer SS1. For example, as illustrated in FIG. 10, the second sub-spacer SS2 may extend along a column direction (e.g., second direction DR2). The second sub-spacer SS2 may have a linear shape.

The second sub-spacer SS2 may be disposed between anode electrodes AND adjacent in the first direction DR1. For example, the second sub-spacer SS2 may be disposed between anode electrodes AND that are adjacent to each other in the same row in the row direction (e.g., first direction DR1). For example, the second sub-spacer SS2 may be disposed between the anode electrodes AND disposed adjacently in the first direction DR1 in the second row RW2.

The second sub-spacer SS2 may connect adjacent first sub-spacers SS1. In an embodiment, the second sub-spacer SS2 and the first sub-spacer SS1 may be integrally or continuously formed.

A region surrounded and defined by the first sub-spacers SS1 and the second sub-spacers SS2 described above may be the spacer area 111 described above. For example, a region surrounded by the first sub-spacers SS1 and the second sub-spacers SS2 disposed adjacent to each other may be defined as the spacer area 111.

At least a portion of the second sub-spacer SS2 may overlap the contact hole CT described above. For example, the second sub-spacer SS2 may extend into the spacer area 111, and the extended portion of the second sub-spacer SS2 may overlap the contact hole CT.

Meanwhile, after forming of the spacer SPC, a trench TRC penetrating the pixel defining layer PDL and the insulating layer INS may be formed as illustrated in FIG. 12. As illustrated in FIG. 10, the trench TRC may surround the anode electrode AND from a plan view. At this time, the trench TRC may be disposed between the anode electrode AND and the spacer SPC from a plan view.

The trench TRC may define a separation area 222, and the anode electrode AND may be disposed within the separation area 222.

As illustrated in FIG. 12, the intermediate layer LPL may be disposed on the pixel defining layer PDL, the spacer SPC, and in the trench TRC. The intermediate layer LPL may be conformally formed at the base of the trench TRC to have substantially the same thickness as on the spacer SPC and the pixel defining layer PDL, and may not fill the trench TRC.

The intermediate layer LPL may include a plurality of light emitting units. For example, the intermediate layer LPL may include a first light emitting unit, a second light emitting unit, and a third light emitting unit stacked in the third direction DR3. The respective light emitting units may provide light of different wavelengths. For example, the first light emitting unit, the second light emitting unit, and the third light emitting unit may emit light of different colors. For example, the intermediate layer LPL may have a tandem structure in which a plurality of light emitting units providing light of different colors are stacked in a vertical direction (e.g., in the third direction DR3).

The first light emitting unit may be disposed on the anode electrode AND. The first light emitting unit may include a first light emitting layer, a hole transporting layer, an organic material layer, and an electron transporting layer.

The second light emitting unit may be disposed on the first light emitting unit. The second light emitting unit may include a second light emitting layer, a hole transporting layer, an organic material layer, and an electron transporting layer.

The third light emitting unit may be disposed on the second light emitting unit. The third light emitting unit may include a third light emitting layer, a hole transporting layer, an organic material layer, and an electron transporting layer.

The light emitting elements may provide white light by mixing light of a first color (e.g., blue) from the first light emitting unit, light of a second color (e.g., red) from the second light emitting unit, and light of a third color (e.g., green) from the third light emitting unit. For example, the light emitting elements may emit white light.

In addition, the intermediate layer LPL may further include at least one charge generation layer in addition to the light emitting unit described above. The charge generation layer may be disposed between the light emitting units adjacent to each other in the third direction DR3, for example. The charge generation layer may include, for example, a first charge generation layer and a second charge generation layer stacked in the third direction DR3. In this case, the first charge generation layer may be disposed between the first light emitting unit and the second light emitting unit, and the second charge generation layer may be disposed between the second light emitting unit and the third light emitting unit.

Meanwhile, each charge generation layer may include a negative charge generating layer and a positive charge generating layer. For example, the first charge generation layer may include a first negative charge generation layer and a first positive charge generation layer stacked in the third direction DR3, and the second charge generation layer may include a second negative charge generation layer and a second positive charge generation layer stacked in the third direction DR3.

As illustrated in FIG. 12, the intermediate layer LPL may be disconnected by the trench TRC extending through the pixel defining layer PDL and the insulating layer INS. For example, as illustrated in FIG. 10 and FIG. 12, the trench TRC may extend through the pixel defining layer PDL and the insulating layer INS to surround the anode electrode AND, and the intermediate layer LPL may be separated into anode electrode units (or pixel units) by this trench TRC to be distinguished. Accordingly, the intermediate layer LPL of each separation area 222 may be physically separated from other islands of the intermediate layer LPL.

As illustrated in FIG. 12, a cathode electrode CAT may be disposed on the intermediate layer LPL. For example, the cathode electrode CAT may be disposed on the intermediate layer LPL to overlap the anode electrode AND, the light emitting area EA, the pixel defining layer PDL, the spacer SPC and the trench TRC. In a top emission structure, the cathode electrode CAT may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). When the cathode electrode CAT is formed of the semi-transmissive conductive material, light emission efficiency may be increased by a micro cavity.

According to the display device 10 of an embodiment, since the insulating layers INS and metal layers are planarized by a chemical mechanical polishing (CMP) process, the pixel defining layer PDL formed by the chemical mechanical polishing process may also be planarized. For example, as illustrated in FIG. 12, a portion of the pixel defining layer PDL on the contact hole CT that connects the drain electrode D of the transistor TR to the anode electrode AND and a portion of the pixel defining layer PDL in which the contact hole CT is not disposed may be planarized without steps. Accordingly, a top layer of the pixel defining layer PDL may be at the same distance from the substrate SSUB in the third direction DR3—i.e., at the same height—in the region overlapping the contact hole CT (hereinafter, an overlapping area) and in the region not overlapping the contact hole CT (hereinafter, a non-overlapping area). The spacer SPC on the pixel defining layer PDL may be at the same distance from the substrate SSUB—i.e., same height—in the overlapping and non-overlapping areas described above. Here, because the height of the pixel defining layer PDL is constant, the spacer SPC may have a substantially constant thickness in the overlapping and non-overlapping areas. Therefore, even if the spacer SPC is disposed on the pixel defining layer PDL to overlap the contact hole CT, the spacer SPC may be at the same height in all portions. In other words, since the entire portions of the spacer SPC may have the same height despite the overlapping between the spacer SPC and the contact hole CT, the role of the spacer to support the mask can be performed normally.

In this way, the spacer SPC may be placed not only in the non-overlapping area described above but also in the overlapping area including the contact hole CT, and as a result, the spacer SPC may overlap more with a mask (e.g., a fine metal mask) placed on the top portion of the spacer SPC. In other words, the supporting area and supporting force of the spacer SPC in respect to the mask may be improved, and thus sagging of the mask can be minimized.

In addition, the spacer SPC may include a first sub-spacer SS1 and a second sub-spacer SS2 connected to each other in the first direction DR1 and the second direction DR2, and thus, tearing or the like of the spacer SPC can be prevented.

Meanwhile, since the anode electrodes AND are placed to form a different shape in plan view between the region in which the contact hole CT is disposed (hereinafter, referred to as the first area; for example, the area between the second row RW2 and the third row RW3 in FIG. 10) and in the region in which the contact hole CT is not disposed (hereinafter, referred to as the second area; for example, the area between the third row RW3 and fourth row RW4 in FIG. 10), the amount of light reflected from the first area and the second area may vary. This difference in the light reflected may result in a color difference between the first area and the second area and deteriorate image quality. For example, while the anode electrodes AND connected to the contact hole CT are densely placed in the first area, the anode electrodes AND are less densely positioned in the second area. IN other words, the anode electrodes AND occupy a greater proportion of the first area than of the second area. Accordingly, the reflectance in the first area may be higher than the reflectance in the second area. However, since the spacer SPC according to an embodiment is disposed on the pixel defining layer PDL to cover both the first and second areas, any color difference problem caused by the reflectance difference between the first and second areas may be solved.

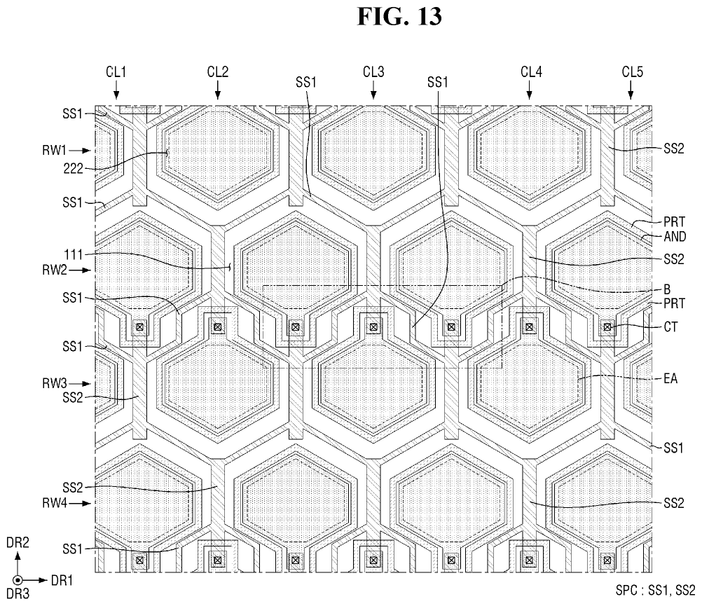

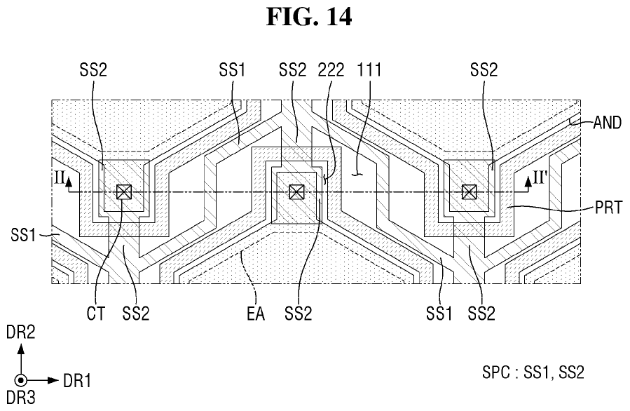

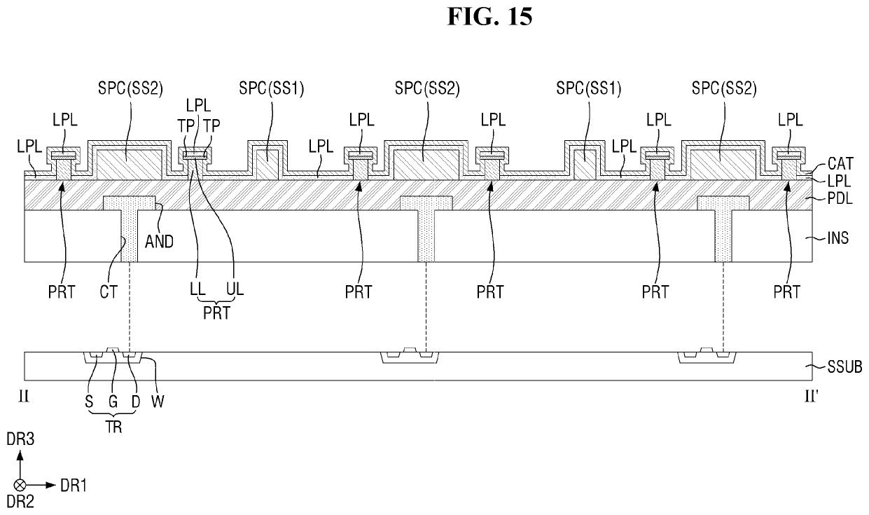

FIG. 13 is a plan view of a display device according to an embodiment, FIG. 14 is an enlarged view of portion B of FIG. 13, and FIG. 15 is a cross-sectional view of a display device taken along line II-II′ of FIG. 14.

The display devices 10 of FIGS. 13 to 15 are different from the display devices 10 of FIGS. 10 to 12 in that the display devices 10 of FIGS. 13 to 15 include a partition wall PRT instead of the trench TRC described above, and such a difference will be mainly described as follows.

Meanwhile, after forming of the spacer SPC, the partition wall PRT may be formed on the pixel defining layer PDL as illustrated in FIG. 15. As illustrated in FIG. 13, the partition wall PRT may surround the anode electrode AND from a plan view. At this time, the partition wall PRT may be disposed between the anode electrode AND and the spacer SPC in a plan view.

The partition wall PRT may define a separation area 222, and the anode electrode AND may be disposed within the separation area 222. The separation area 222 may form a border along the edge region of the anode AND, as shown in FIG. 10.

The partition wall PRT may include a lower layer LL and an upper layer UL.

The lower layer LL may be disposed on the pixel defining layer PDL, and the upper layer UL may be disposed on the lower layer LL.

At least one side of the upper layer UL may protrude (or extend) further than the lower layer LL in at least one of the first direction DR1 and the second direction DR2 so as not to be supported by the lower layer LL. In other words, at least one side of the upper layer UL may extend beyond the edge of the lower layer LL in the first direction DR1 and the second direction DR2, thereby forming a tip TP. Specifically, the lower layer LL may support the upper layer UL in the third direction DR3, and the upper layer UL may form the tip TP extending beyond the edges of the lower layer LL in a direction intersecting the third direction DR3 (for example, at least one direction of the first direction DR1 and the second direction DR2) on the lower layer LL. This tip TP is not supported by the lower layer LL. Accordingly, a virtual extension line extending along the side of the lower layer LL may intersect the upper layer UL. For example, the area of the upper layer UL may be greater than the area of the top surface of the lower layer LL from a plan view. Here, the area of the upper layer UL may mean, for example, an area defined by the size of the upper layer UL in a plane defined by the first direction DR1 and the second direction DR2, and the area of the top surface of the lower layer LL may mean an area defined by the size of the top surface of the lower layer LL in a plane defined by the first direction DR1 and the second direction DR2. Accordingly, the tip TP of the upper layer UL may not be in contact with the lower layer LL. Due to the tip TP of the upper layer UL, an undercut may occur on the lower side of the tip TP when forming the partition wall PRT. Accordingly, at least one side of the partition wall PRT may have an overhang structure.

As illustrated in FIG. 15, the intermediate layer LPL may be disconnected by the partition wall PRT on the pixel defining layer PDL. For example, as illustrated in FIG. 13, the partition wall PRT may be disposed on the pixel defining layer PDL to surround the anode electrode AND, and the intermediate layer LPL may be separated into anode electrode units (or pixel units) by this partition wall PRT to be distinguished. Accordingly, the intermediate layer LPL of each separation area 222 may be physically separated.

As illustrated in FIG. 15, the intermediate layer LPL may be disposed on the pixel defining layer PDL, the spacer SPC, and the partition wall PRT.

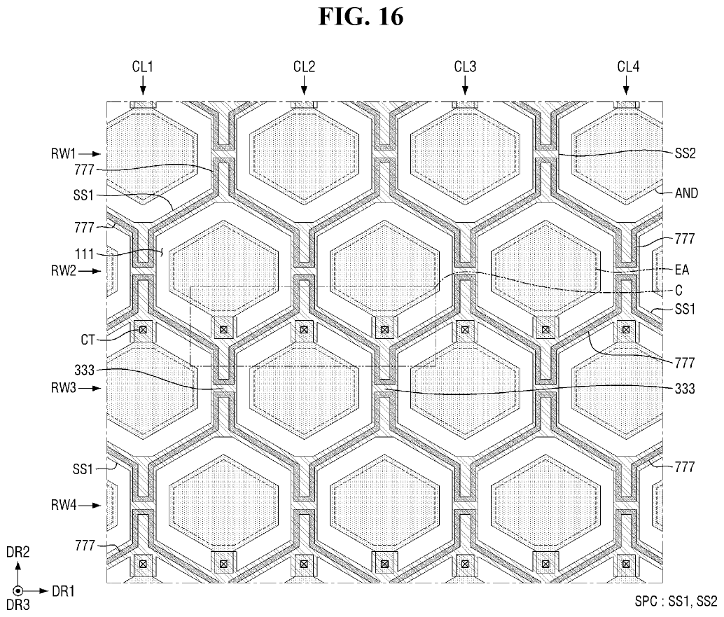

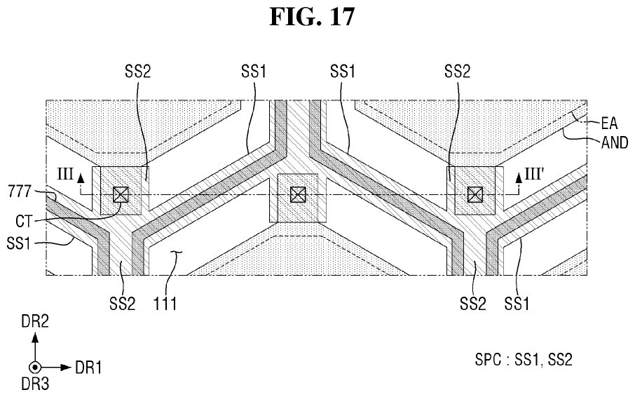

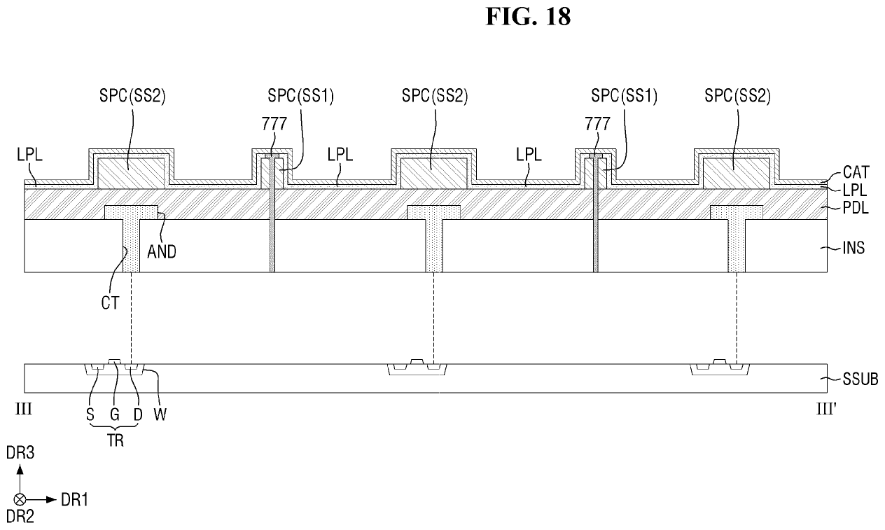

FIG. 16 is a plan view of a display device according to an embodiment, FIG. 17 is an enlarged view of portion C of FIG. 16, and FIG. 18 is a cross-sectional view of a display device taken along line III-III′ of FIG. 17.

The display devices of FIGS. 16 to 18 are different from the display devices 10 of FIGS. 10 to 12 in that the display devices of FIGS. 16 to 18 include a heating electrode 777 instead of the trench TRC described above, and such a difference will be mainly described as follows.

After forming of the spacer SPC, the heating electrode 777 may be formed on the spacer SPC as illustrated in FIG. 18. Meanwhile, the heating electrode 777 may be further disposed in a contact hole penetrating the spacer SPC and the pixel defining layer PDL.

As illustrated in FIG. 16, the heating electrodes 777 may be disposed along the spacer SPC. In other words, the heating electrode 777 may be disposed on the spacer SPC to overlap the first sub-spacer SS1 and the second sub-spacer SS2 of the spacer SPC. From a plan view, the heating electrode 777 may be entirely covered by the spacer SPC.

As illustrated in FIG. 16, the heating electrode 777 may be formed around the anode electrode AND in a plan view. In the embodiment of FIG. 16, the heating electrode 777 may surround most of the anode electrode AND but have an opening 333 connecting between the adjacent spacer regions 111.

The heating electrode 777 may be connected to the power supply unit through the contact hole 701 described above. The power supply unit may apply voltage (or current) to the heating electrode 777. The heating electrode 777 may be heated to a high temperature by the voltage (or current) applied to the heating electrode 777, and the intermediate layer LPL may be disconnected by this heated heating electrode 777. For example, in the manufacturing process sequence, the intermediate layer LPL may be formed after the heating electrode 777 is disposed. When voltage (or current) is applied to the heating electrode 777, the portion of the intermediate layer LPL around the heating electrode 777 may be removed. In other words, the intermediate layer LPL may be removed by the heat of the heating electrode 777. For example, the portion of the intermediate layer LPL on the heating electrode 777 may be removed. Then, the intermediate layer LPL may be separated into anode electrode units (or pixel units) to be distinguished. Accordingly, the intermediate layer LPL of the spacer regions 111 may be physically separated from one another.

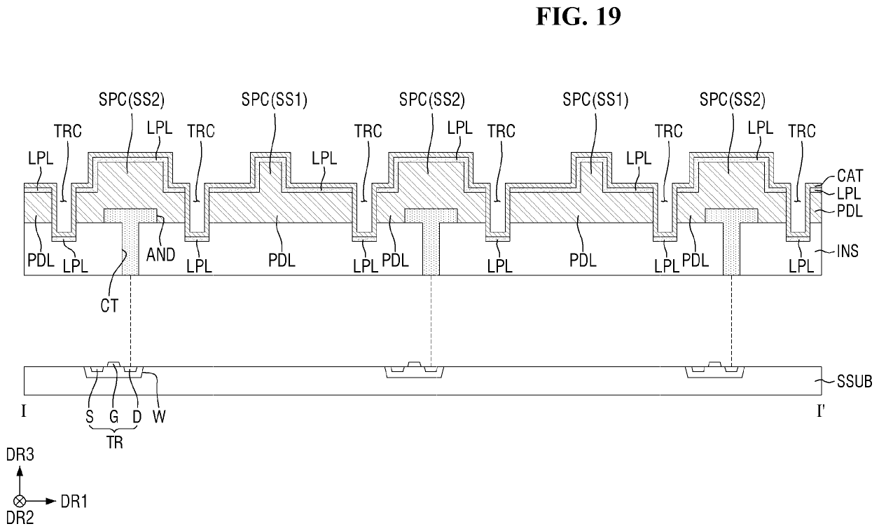

FIG. 19 is a plan view of a display device according to an embodiment.

The display device of FIG. 19 is different from the display device 10 of FIG. 12 in that the pixel defining layer PDL and the spacer SPC are integrally formed. The following description of the embodiment of FIG. 19 will focus on this difference.

As illustrated in FIG. 19, the pixel defining layer PDL and the spacer SPC may be integrally formed. In other words, the pixel defining layer PDL and the spacer SPC may be made of the same material. A structure including the pixel defining layer PDL and the spacer SPC may be manufactured by using, for example, a half-tone exposure method.

Although not illustrated, the pixel defining layer PDL and the spacer SPC may also be integrally formed in FIGS. 15 and 18. In other words, the pixel defining layer PDL and the spacer SPC may be made of the same material in the embodiments of FIGS. 15 and 18.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a substrate;
a transistor on the substrate;
a first electrode connected to the transistor; and
a spacer disposed on the first electrode,
wherein the spacer overlaps a connection portion between the transistor and the first electrode.

2. The display device of claim 1, further comprising an insulating layer between the transistor and the first electrode,
wherein the connection portion extends through a contact hole in the insulating layer.

3. The display device of claim 2,
wherein the spacer overlaps the contact hole.

4. The display device of claim 3,
wherein the first electrode is disposed in the contact hole.

5. The display device of claim 1,
wherein the spacer surrounds the first electrode in plan view and overlaps the connection portion between the transistor and the first electrode.

6. The display device of claim 1,
wherein the spacer comprises:
a first sub-spacer disposed between the first electrodes of the adjacent rows; and
a second sub-spacer disposed between the adjacent first sub-spacers and overlaps the connection portion between the transistor and the first electrode.

7. The display device of claim 6,
wherein the first sub-spacer extends in the row direction, and
wherein the second sub-spacer extends in the column direction intersecting the row direction.

8. The display device of claim 6,
wherein the second sub-spacer is connected to the adjacent first sub-spacers.

9. The display device of claim 8,
wherein the second sub-spacer and the first sub-spacer are integrally formed.

10. The display device of claim 6,
wherein the first sub-spacer has a zig-zag form.

11. The display device of claim 6,
wherein the second sub-spacer are disposed in plurality between the adjacent first sub-spacers.

12. The display device of claim 11,
wherein the first electrode is disposed in a region surrounded and defined by the adjacent first sub-spacers and the adjacent second sub-spacers.

13. The display device of claim 1, further comprising a pixel defining layer disposed between the first electrode and the spacer.

14. The display device of claim 13,
wherein the connection portion extends through a contact hole in an insulating layer between the transistor and the first electrode, and
wherein a top surface of the pixel defining layer is at the same distance from the substrate in an overlapping area and a non-overlapping area with the contact hole.

15. The display device of claim 13,
wherein pixel defining layer has a trench surrounding the first electrode.

16. The display device of claim 15,
wherein the spacer surrounds the trench.

17. The display device of claim 13,
wherein the spacer and the pixel defining layer are integrally formed.

18. The display device of claim 13, further comprising a partition wall disposed on the pixel defining layer.

19. The display device of claim 18,
wherein the partition wall comprises:
a lower layer on the pixel defining layer; and
an upper layer on the lower layer.

20. The display device of claim 13, further comprising a heating electrode on the spacer.

21. The display device of claim 20,
wherein the heating electrode is disposed in a contact hole extending through the spacer and the pixel defining layer.

22. The display device of claim 1,
wherein the spacer has a black color.

23. The display device of claim 1, further comprising:
an intermediate layer on the first electrode; and
a second electrode on the intermediate layer.
